(19) United States
(12) Patent Application Publication
(10) Pub. No.: US 2008/0238304 A1
(43) Pub. Date: Oct. 2, 2008

(54) ELECTRO-OPTICAL LUMINOUS MEANS COMPRISING ORGANIC LIGHT-EMITTING MATERIAL

(75) Inventors: Frank Schmid, Poppenricht (DE); Oliver Klettke, Nurnberg (DE)

Correspondence Address: SCULLY SCOTT MURPHY & PRESSER, PC, 400 GARDEN CITY PLAZA, SUITE 300, GARDEN CITY, NY, 11530, US

(73) Assignee: DIEHL AEROSPACE GMBH, Uberlingen (DE)

(21) Appl. No.: 12/026,739

(22) Filed: Feb. 6, 2008

(30) Foreign Application Priority Data
Feb. 6, 2007 (DE) 102007005692.5
Mar. 21, 2007 (DE) 202007004137.3

(51) Int. Cl. H01L 51/50

(52) U.S. Cl. 313/504

(57) ABSTRACT

The temperature dependence of the most important characteristics of OLEDs (11) can be effectively counteractively controlled by the power supply (18) thereof if the actual instantaneous operating temperature is detected metrologically by at least one temperature sensor (19) incorporated into the hermetically encapsulated OLED (11). For this purpose, a line section (20) composed of a material having a high temperature coefficient of its electrical resistance is applied in electrically insulated fashion to one of the electrodes (areal transparent anode 13 or geometrically structured cathode 16), in a manner facing or averted from the polymer (14). If the temperature sensor (19) is arranged before the cathode on the emission side, that is to say even if it is arranged at the anode (13), its line section (20) preferably runs outside the projection of those geometrically structured regions of the cathode (16) which govern the cross-sectional geometries of the polymer excitation and thus of the emissions (15).

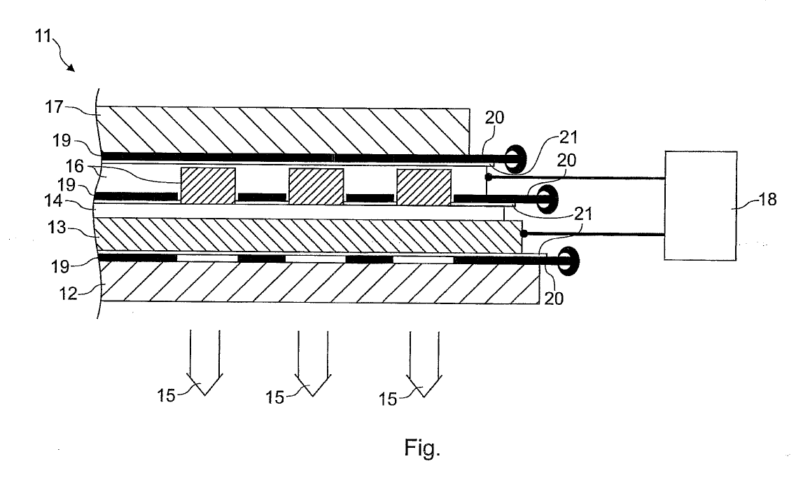

### BACKGROUND OF THE INVENTION

1. Field of the Invention

The invention relates to an electro-optical luminous means, which comprises an organic light-emitting material arranged between two electrodes, for example, a transparent anode and a geometrically structured cathode, such as is often also referred to in a simplified manner as OLED.

2. Discussion of the Prior Art

The construction of such an OLED; for instance, is known from the journals FUNKSCHAU, Issue 19/1995 (page 66, on the right), or ELEKTRONIK, Issue 17/1999 (page 76, on the right). Accordingly, essentially a transparent substrate has applied to it an, if appropriate intrinsically conductively coated, metallic anode (in particular, which is composed of indium tin oxide) and the latter has applied to it a very uniformly very thin layer of an organic material such as e.g. a polymer that emits light upon electrical excitation. The geometry of the light emission is determined by the form of a metallic cathode which is then applied by vapour deposition at the back by means of masks and is also covered with a protective layer against external mechanical influences. Thus, it is possible to produce very thin luminous means having a very high luminous intensity, such as displays, for example, which are even flexible if, rather than glass plates, flexible plastic films are employed for the emission-side substrate and for the rear protective covering.

It has been found that the characteristics of such OLEDs that are primarily of interest for practical use, such as the lifetime, the bright-dark changeover dynamic range and primarily the colour locus (frequency spectrum of the light emission), are very dependent on the operating temperature of the emitting organic material (e.g. polymer). Therefore, in functionally critical applications under greatly fluctuating ambient conditions, such as, in particular, in instruments of land vehicles or aircraft, the instantaneous temperature is measured before or behind the OLED and a thermal model of the OLED construction is used to deduce the actual temperature in the hermetically encapsulated light-active layer. However, due to system dictates, such calculation models only provide estimations which are inadequate by virtue of their being virtually unreproducible.

### SUMMARY OF THE INVENTION

In recognition of these circumstances, the present invention is based on the technical problem of further developing a luminous means of the generic type to the effect that the temperature-dependent characteristics can be controlled better during operation.

This object is achieved according to the invention in that a temperature sensor is arranged on one of the electrodes. Accordingly, at least one structure which is electrically conductive in a temperature-dependent manner and is additionally introduced into the interior of the OLED is used to measure indirectly or directly the actual instantaneous temperature on at least one side of the light-generating layer. As a result, for a thermal optimization in the course of OLED operation, without the complicated yet unreliable detour via a mathematical model calculation on the basis of external temperature measurements, valid temperature values can be obtained directly from the organic material itself.

For such OLED-internal temperature measurement, the metallic anode and/or cathode can serve as heat mediator and sensor carrier, to which a for instance meandering course of a greatly temperature-dependent electrical conductor, for instance based on platinum, with interposition of a thin electrically insulating layer, is applied by printing or is applied by vapour deposition by means of a masking. This line section which is linear or preferably runs in meandering fashion leads with its beginning and its end to respective connection contacts accessible from outside the OLED for constant current or voltage feeding for temperature measurement.

Instead or in addition, however, provision may also be made for applying directly to the light-generating organic material at least one such temperature sensor, preferably only with interposition of an electrically insulating compensating layer, that is to say without a metallic heat conductor in the form of the anode and/or cathode.

Therefore, according to the invention, the temperature dependence of the most important characteristics of OLEDs can be effectively counteractively controlled by means of the power supply thereof, if the actual instantaneous operating temperature is detected metrologically by means of at least one temperature sensor incorporated into the hermetically encapsulated OLED. For this purpose, a line section composed of a material having a high temperature coefficient of its electrical resistance is applied in electrically insulated fashion to one of the electrodes (to the whole-area transparent anode or preferably to the geometrically structured cathode), in a manner averted from the organic material or on the organic material. If the temperature sensor is arranged before the cathode on the emission side, that is to say even if it is arranged at the anode, its meandering or oscillating line section preferably runs outside the projection of those geometrically structured regions of the cathode which govern the cross-sectional geometries of the excitation of the organic material and thus of the emissions.

### BRIEF DESCRIPTION OF THE DRAWINGS

Additional alternatives and developments with respect to the solution according to the invention emerge from the further claims and, also with regard to their advantages, from the description below of preferred embodiments of such solutions. The single FIGURE of the drawing shows, in a generally diagrammatic manner with respect to the stepped edge and in a greatly enlarged manner not to scale, in truncated section through an OLED of a display, advantageous arrangements of temperature sensors in the OLED according to the present invention.

### DETAILED DESCRIPTION OF THE INVENTION

In contrast to what is outlined schematically for illustrating the layer construction, the OLED 11 outlined schematically is not actually offset in stepped fashion, but rather closed off hermetically with a planar edge. An emission-side, rigid or flexible transparent substrate 12 carries a likewise transparent, areal anode 13 for instance in the form of an ITO layer (indium tin oxide), and the latter carries a very thin coating composed of a polymer 14 as organic material, the molecules of which react to a recombination of injected positive and negative charge carriers (holes and electrons), with the emission 15 of light. For this purpose, a geometrically structured cathode 16, which determines the contours of the emissions 15, is printed on the polymer 14 or applied to the polymer 14 by mask vapour deposition. A protective layer 17 against mechanical influences and for hermetically closing off the OLED 11 at the back, for instance a glass plate, terminates said OLED opposite the emission 15.

For the operation of the OLED 11, a pulse-width-modulatable high-impedance electrical supply 18 is connected between the two metallic electrodes, that is to say anode 13 and cathode 16. The pulse amplitude of this current source influences (for given polymer molecules) the colour locus, that is to say the spectrum, of the emission 15, and the pulse width, that is to say the impressed average supply current, influences the brightness of the emission 15. In particular these two characteristics of the OLED 11, which are significant for practical use, are also determined, however, by the operating temperature of the polymer 14, which fluctuates depending on the ambient conditions at the site of use and also depending on the average supply current.

In order to be able to effectively and rapidly counteractively control such phenomena from the supply 18, the actual instantaneous temperature of the polymer 14 should be determined in a manner that is as up to date and accurate as possible. For this purpose, the OLED 11 is equipped with at least one integrated temperature sensor 19 on one of the electrodes, which temperature sensor therefore detects the instantaneous temperature of the polymer 16 practically directly and correspondingly accurately. As temperature sensor 19, at least one electrically closed line section 20 running in oscillating or meandering fashion and composed of a material such as platinum is applied (by printing or by vapour deposition by means of a mask) on at least one electrode, the electrical resistance of said material, which can be determined from the supply current and supply voltage via Ohm's law, being greatly dependent on the temperature.

A thin insulating layer 21 between the respective electrode (anode 13 or cathode 16) and the temperature sensor 19 ensures that the electrode does not electrically short-circuit the line section 20 running in curved fashion or the line section 20 does not electrically short-circuit the structuring of the cathode 16.

In the case of a temperature sensor 19 which is introduced between the polymer 14 and an electrode (anode 13 or, as outlined schematically in the middle case, cathode 16) and is electrically insulated again from the adjacent electrode and the polymer 14, said temperature sensor preferably extends, as outlined schematically, only over regions whose projections onto the substrate 12 do not coincide with light emissions 15, that is to say only over regions between the injection structures of the cathode 16. This correspondingly also applies to the arrangement of a temperature sensor 19 on the anode 13 (outlined schematically towards the bottom in the drawing), to be precise here both on its side facing the polymer 14 and on the side averted from the latter. This avoids the problems of having to inject charge carriers into the polymer 14 through an insulation, or not partly shading the optically active regions of the polymer 14 by line sections 20 of a temperature sensor 19 in the light emission 15.

Since it is generally known to use as organic light-emitting material, instead of a polymer, also other materials such as e.g. dendrimers or materials containing organic molecules comprising few atoms (so- called small molecules), the present invention relates to OLEDs having any type of organic material for the light-emitting layer, in particular of course to OLEDs having the materials mentioned.

### LIST OF REFERENCE SYMBOLS

11 OLED
12 Substrate
13 Anode
14 Polymer
15 Emission
16 Cathode
17 Protective layer
18 Supply
19 Temperature sensor
20 Line section
21 Insulation layer

What is claimed is:

1. An electro-optical luminous means (11) comprising an organic light-emitting material, which is arranged between two electrodes and wherein a temperature sensor (19) is arranged on one of the electrodes.

2. An electro-optical luminous means according to claim 1, wherein the temperature sensor (19) is a line section (20) composed of a material having a highly temperature-dependent electrical resistance.

3. An electro-optical luminous means according to claim 2, wherein said line section (20) extends in an oscillating or meandering manner with a platinum-containing material being applied by selectively printing or vapor deposition.

4. An electro-optical luminous means according to claim 1, wherein an electrical insulation layer (21) is formed between the temperature sensor (19) and said electrode.

5. An electro-optical luminous means according to claim 1, wherein the temperature sensor (19) is provided in regions whose projection does not coincide with regions of emissions (15).

6. An electro-optical luminous means according to claim 1, wherein the temperature sensor (19) is arranged on the organic light-emitting material.

7. An electro-optical luminous means according to claim 1, wherein said two electrodes comprise, respectively, a transparent anode (13) and a geometrically structured cathode (16).
